(19) United States
(12) Patent Application Publication
(10) Pub. No.: US 2023/0088223 A1
(43) Pub. Date: Mar. 23, 2023

(54) METHODS, SYSTEMS, AND APPARATUS FOR PROVIDING A DRILLING INTERPRETATION AND VOLUMES ESTIMATOR

(71) Applicant: Minerva Intelligence Inc., Vancouver (CA)

(72) Inventors: Clinton Paul Smyth, Vancouver (CA); Alexander Michael Wilson, Highlands (CA)

(73) Assignee: Minerva Intelligence Inc., Vancouver, BC (CA)

(21) Appl. No.: 17/802,785

(22) PCT Filed: Feb. 26, 2021
(86) PCT No.: PCT/CA2021/050254

§ 371 Date: Aug. 26, 2022

(30) Foreign Application Priority Data
Feb. 28, 2020 (CA) 3074149
Feb. 25, 2021 (CA) 3110373

(51) Int. Cl. G01V 99/00; G06F 30/27

(52) U.S. Cl. CPC G01V 99/005; G06F 30/27

(57) ABSTRACT

A drilling interpretation and volumes estimator (DRIVER) system may be provided. The DRIVER system may help facilitate a cost-effective discovery of patterns in mineral exploration drilling data that a mining company may not have the human or computer resources to look for. The DRIVER system may be able to reason with those patterns against previously-documented knowledge and may produce conclusions of value to a user, such as a mining professional.

### BACKGROUND

Mineral resource evaluation may require the drilling of one or more boreholes into a targeted mineral deposit, which may yield thousands of samples that may be used to estimate the grade, mineralogy, size and structure of the deposit. Because modern analytical methods often automatically provide accurate concentrations of multiple elements, borehole samples may be analyzed for one or more (e.g., many more) elements than the element in the deposit of primary economic significance.

While most mining companies may devote significant human and computer resources to interpreting their primary economic significance drilling results, they may do not have the resources to interpret the other analytical data available from their drilling programs, even though this data may contain patterns of great economic value.

### SUMMARY OF THE INVENTION

Disclosed herein are systems, methods, and apparatus for providing a drilling interpretation and volumes estimator (DRIVER). The DRIVER system may help facilitate a cost-effective discovery of patterns (e.g., important patterns) in mineral exploration drilling data that most mining companies may not have the human or computer resources to look for. The DRIVER system may be able to reason with those patterns against documented knowledge (e.g., previously documented knowledge) and may produce conclusions of value to a user, such as a mining professional.

The DRIVER system may identify anomalous geochemical zones and patterns of potential economic significance. Clusters of block values within the models may be identified that may be higher or lower (e.g., significantly higher or lower) than their surrounding block values and may be tagged as anomalous. Discrete (non-contiguous) clusters of anomalous block values may be determined and may one or more discrete clusters (e.g., each discrete cluster) may be named. One or more such clusters (e.g., each such cluster) may be considered to represent a geochemical zone. Spatial relationships between such zones of different elements may be identified. For example, an extent of zone overlap may be identified, which may be aggregated over the entire study volume, or in individual zones. Cognitive artificial intelligence (AI) technology may be used to report which identified spatial patterns may be of possible economic importance to the mineral deposit being evaluated, and why they may be important.

A device may be provided for modeling an anomalous geochemical zones. The device may comprise a memory and a processor that may be configured to perform a number of actions. The processor may be configured to determine block values by interpolating, using various anisotropies, multi-element assay results from drill hole samples into contiguous blocks used to model a volume sampled by drilling. The processor may be configured to identify clusters of the block values for an element within each of multiple models representing the various anisotropies, the clusters may indicate which block values may be anomalous to one or more surrounding block values. The processor may be configured to determine an optimal anisotropy for each element from the identified clusters, by performing a statistical directional analysis on the identified clusters for each element. The processor may be configured to surround a space occupied by each cluster associated with the optimal anisotropy for each element, with a wireframe, each representing a geochemical zone.

A method for modeling anomalous geochemical zones may be provided. The method may comprise determining block values by interpolating, using various anisotropies, multi-element assay results from drill hole samples into contiguous blocks used to model a volume sampled by drilling. The method may comprise identifying clusters of the block values for an element within each of multiple models representing the various anisotropies, the clusters indicating which block values are anomalous to one or more surrounding block values. The method may comprise determining an optimal anisotropy for each element from the identified clusters by performing a statistical directional analysis on the identified clusters for each element. The method may comprise surrounding a space occupied by each cluster associated with the optimal anisotropy for each element, with a wireframe, each representing a geochemical zone.

This Summary is provided to introduce a selection of concepts in a simplified form that are further described herein in the Detailed Description. This Summary is not intended to identify key features or essential features of the claimed subject matter, nor is it intended to be used to limit the scope of the claimed subject matter. Other features are described herein.

### BRIEF DESCRIPTION OF THE DRAWINGS

The Summary and the Detailed Description may be better understood when read in conjunction with the accompanying exemplary drawings. It is understood that the potential embodiments of the disclosed systems and implementations are not limited to those depicted.

FIG. 1 shows an example computing environment that may be to provide a drilling interpretation and volumes estimate (DRIVER) system.

FIG. 2 shows an example flow diagram integrating artificial intelligence (e.g., cognitive artificial intelligence) into the DRIVER system.

FIG. 3 shows an example illustration of one or more modules that may be used in a DRIVER system.

FIG. 4 shows an example flow diagram for providing a drilling interpretation and volumes estimator.

FIG. 5 shows an example block model as displayed in a 3D software.

FIGS. 6A-B show examples of enhanced zone wireframes

FIG. 7A-B show example concentration (C) with respect to volume (V) plots (CV plots).

FIGS. 8A-B show example CV plots that consider an ellipsoid aspect ratio.

FIG. 9 shows an example CV plot of Pb in an example deposit.

FIG. 10A-B show an example distribution of data grouped into spatially discrete cluster groups.

FIGS. 11A-C show example Tin (Sn) groups arising from optimal anisotropy analysis for an example deposit.

FIGS. 12A-C show discount groups that may be identified for Zn.

FIGS. 13A-B show example representations of ellipsoid surface area data.

FIGS. 14A-B show examples of bi-variate histograms.

### DETAILED DESCRIPTION

A detailed description of illustrative embodiments will now be described with reference to the various Figures. Although this description provides a detailed example of possible implementations, it should be noted that the details are intended to be exemplary and in no way limit the scope of the application.

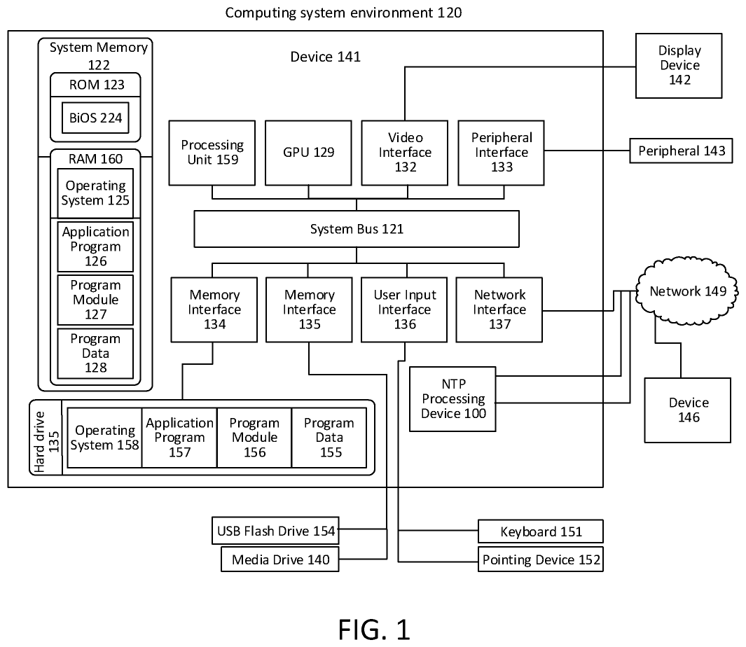

FIG. 1 shows an example computing environment that may be used for probabilistic reasoning. Computing system environment 120 is not intended to suggest any limitation as to the scope of use or functionality of the disclosed subject matter. Computing environment 120 should not be interpreted as having any dependency or requirement relating to the components illustrated in FIG. 1. For example, in some cases, a software process may be transformed into an equivalent hardware structure, and a hardware structure may be transformed into an equivalent software process. The selection of a hardware implementation versus a software implementation may be one of design choice and may be left to the implementer.

The computing elements shown in FIG. 1 may include circuitry that may be configured to implement aspects of the disclosure. The circuitry may include hardware components that may be configured to perform one or more function(s) by firmware or switches. The circuity may include a processor, a memory, and/or the like, which may be configured by software instructions. The circuitry may include a combination of hardware and software. For example, source code that may embody logic may be compiled into machine-readable code and may be processed by a processor.

As shown in FIG. 1, computing environment 120 may include device 141, which may be a computer, and may include a variety of computer readable media that may be accessed by device 141. Device 141 may be a computer, a cell phone, a server, a database, a tablet, a smart phone, and/or the like. The computer readable media may include volatile media, nonvolatile media, removable media, non-removable media, and/or the like. System memory 122 may include read only memory (ROM) 123 and random access memory (RAM) 160. ROM 123 may include basic input/output system (BIOS) 124. BIOS 124 may include basic routines that may help to transfer data between elements within device 141 during start-up. RAM 160 may include data and/or program modules that may be accessible to by processing unit 159. ROM 123 may include operating system 125, application program 126, program module 127, and program data 128.

Device 141 may also include other computer storage media. For example, device 141 may include hard drive 138, media drive 140, USB flash drive 154, and/or the like. Media drive 140 may be a DVD/CD drive, hard drive, a disk drive, a removable media drive, flash memory cards, digital versatile disks, digital video tape, solid state RAM, solid state ROM, and/or the like. The media drive 140 may be internal or external to device 141. Device 141 may access data on media drive 140 for execution, playback, and/or the like. Hard drive 138 may be connected to system bus 121 by a memory interface such as memory interface 134. Universal serial bus (USB) flash drive 154 and media drive 140 may be connected to the system bus 121 by memory interface 135.

As shown in FIG. 1, the drives and their computer storage media may provide storage of computer readable instructions, data structures, program modules, and other data for device 141. For example, hard drive 138 may store operating system 158, application program 157, program module 156, and program data 155. These components may be or may be related to operating system 125, application program 126, program module 127, and program data 128. For example, program module 127 may be created by device 141 when device 141 may load program module 156 into RAM 160.

Device 141 may be a stand-alone device, such as a stand-alone computer, or may be a cloud computing device, such as a server hosted on a cloud computing service. Device 141 may also be a virtual machine, such as virtual machine that may be deployed on a server hosted on a cloud computing service.

A user may enter commands and information into the device 141 through input devices such as keyboard 151 and pointing device 152. Pointing device 152 may be a mouse, a trackball, a touch pad, and/or the like. Other input devices (not shown) may include a microphone, joystick, game pad, scanner, and/or the like. Input devices may be connected to user input interface 136 that may be coupled to system bus 121. This may be done, for example, to allow the input devices to communicate with processing unit 159. User input interface 136 may include a number of interfaces or bus structures such as a parallel port, a game port, a serial port, a USB port, and/or the like.

Device 141 may include graphics processing unit (GPU) 129. GPU 129 may be connected to system bus 121. GPU 129 may provide a video processing pipeline for high speed and high-resolution graphics processing. Data may be carried from GPU 129 to video interface 132 via system bus 121. For example, GPU 129 may output data to an audio/video port (A/V) port that may be controlled by video interface 132 for transmission to display device 142.

Display device 142 may be connected to system bus 121 via an interface such as a video interface 132. Display device 142 may be a liquid crystal display (LCD), an organic light-emitting diode (OLED) display, a touchscreen, and/or the like. For example, display device 142 may be a touchscreen that may display information to a user and may receive input from a user for device 141. Device 141 may be connected to peripheral 143. Peripheral interface 133 may allow device 141 to send data to and receive data from peripheral 143. Peripheral 143 may include an accelerometer, an e-compass, a satellite transceiver, a digital camera (for photographs or video), a USB port, a vibration device, a television transceiver, a hands free headset, a Bluetooth® module, a frequency modulated (FM) radio unit, a digital music player, a media player, a video game player module, a speaker, a printer, and/or the like.

Device 141 may operate in a networked environment and may communicate with a remote computer such as device 146. Device 146 may be a computer, a server, a router, a tablet, a smart phone, a peer device, a network node, and/or the like. Device 141 may communicate with device 146 using network 149. For example, device 141 may use network interface 137 to communicate with device 146 via network 149. Network 149 may represent the communication pathways between device 141 and device 146. Network 149 may be a local area network (LAN), a wide area network (WAN), a wireless network, a cellular network, and/or the like. Network 149 may use Internet communications technologies and/or protocols. For example, network 149 may include links using technologies such as Ethernet, IEEE 802.11, IEEE 806.16, WiMAX, 3GPP LTE, 5G New Radio (5G NR), integrated services digital network (ISDN), asynchronous transfer mode (ATM), and/or the like. The networking protocols that may be used on network 149 may include the transmission control protocol/Internet protocol (TCP/IP), the hypertext transport protocol (HTTP), the simple mail transfer protocol (SMTP), the file transfer protocol (FTP), and/or the like. Data exchanged may be exchanged via network 149 using technologies and/or formats such as the hypertext markup language (HTML), the extensible markup language (XML), and/or the like. Network 149 may have links that may be encrypted using encryption technologies such as the secure sockets layer (SSL), Secure HTTP (HTTPS) and/or virtual private networks (VPNs).

Device 141 may include network timing protocol (NTP) processing device 100. NTP processing device may be connected to system bus 121 and may be connected to network 149. NTP processing device 100 may have more than one connection to network 149.

Mineral resource evaluation may require the drilling of one or more boreholes into a targeted mineral deposit, which may yield thousands of samples that may be used to estimate the grade, mineralogy, size and structure of the deposit. Because modern analytical methods often automatically provide accurate concentrations of multiple elements, borehole samples may be analyzed for one or more (e.g., many more) elements than the element in the deposit of primary economic significance.

While most mining companies may devote significant human and computer resources to interpreting their primary economic significance drilling results, they may not have the resources to interpret the other analytical data available from their drilling programs, even though this data may contain patterns of economic value (e.g., great economic value).

The DRIVER system may help facilitate a cost-effective discovery of patterns (e.g., important patterns) in mineral exploration drilling data that mining companies may not have the human or computer resources to look for. The DRIVER system may achieve this using a number of methodologies. In an example, the DRIVER system may generate multiple three-dimensional (3D) block models, such as geochemical block models that may be consistent with an input collection (e.g., a single input collection) of drilling results, but may postulate multiple possible anisotropies.

The DRIVER may incorporate one or more workflows. The DRIVER system may perform analysis. The DRIVER system may produce output for a user. For example, the DRIVER system may output data delineate or may be used to identify an anisotropy that may control the distribution of element concentrations. The DRIVER system may output data that may be used to compare against a mineral deposit data base. The output data may be used by artificial intelligence (AI), and may be compared and/or analyzed against a database of mineral deposit types and examples. The DRIVER system may include a user interface that may be used for initiating and/or analyzing DRIVER output data.

A block may be provided. A block may be a volume in space used to model the solid earth with specified dimensions in orthogonal directions, to which various properties, such as chemical composition, densities, and the like may be assigned.

A block model may be provided. A block model may be a collection of blocks used to model a volume of the solid earth greater than the size of a single block.

A block value may be provided. A block value may be a property assigned to a block which may be qualitative or quantitative. For example, a chemical concentration, a rock type, and the like.

An anisotropy may be provided. An anisotropy may have a property that has a different value when measured in different directions.

An optimal anisotropy may be provided. An optimal anisotropy may be that anisotropy which best represents the true distribution of the variable in the volume or space modeled.

A cluster may be provided. A cluster may be group of blocks with a common property that separate or distinguish them from surrounding blocks.

A geochemical zone may be provided. A geochemical zone may be a three-dimensional volume with one or more geochemical properties

A spatial relationship may be provided. A spatial relationship may be a relationship in terms of such concepts as containment, overlap, adjacency, and the like, between geochemical zones and the volume sampled by drilling in which the geochemical zones occur.

A device may be provided for modeling an anomalous geochemical zones. The device may comprise a memory and a processor that may be configured to perform a number of actions. The processor may be configured to determine block values by interpolating, using various anisotropies, multi-element assay results from drill hole samples into contiguous blocks used to model a volume sampled by drilling. The processor may be configured to identify clusters of the block values for an element within each of multiple models representing the various anisotropies, the clusters may indicate which block values may be anomalous to one or more surrounding block values. The processor may be configured to determine an optimal anisotropy for each element from the identified clusters, by performing a statistical directional analysis on the identified clusters for each element. The processor may be configured to surround a space occupied by each cluster associated with the optimal anisotropy for each element, with a wireframe, each representing a geochemical zone.

In an example, the statistical directional analysis on the identified clusters may comprise at least a frequency analysis on properties of the identified clusters.

In an example, the processor may be further configured to determine a spatial relationship between a first geochemical zone and a second geochemical zone.

In an example, the spatial relationship may be an overlap between the first geochemical zone and the second geochemical zone.

In an example, the processor may be further configured to generate a description of the overlap between the first geochemical zone and the second geochemical zone. The description may state properties of the overlap.

In an example, the processor may be further configured to generate a description of the spatial relationship. The description may natural language terms interoperable with human knowledge on a computer.

In an example, processor may be further configured to determine, using computer reasoning, mineral deposit types and mineral deposits matching the description of the spatial relationship.

A method for modeling anomalous geochemical zones may be provided. The method may comprise determining block values by interpolating, using various anisotropies, multi-element assay results from drill hole samples into contiguous blocks used to model a volume sampled by drilling. The method may comprise identifying clusters of the block values for an element within each of multiple models representing the various anisotropies, the clusters indicating which block values are anomalous to one or more surrounding block values. The method may comprise determining an optimal anisotropy for each element from the identified clusters by performing a statistical directional analysis on the identified clusters for each element. The method may comprise surrounding a space occupied by each cluster associated with the optimal anisotropy for each element, with a wireframe, each representing a geochemical zone.

In an example, the statistical directional analysis on the identified clusters may comprise at least a frequency analysis on properties of the identified clusters.

In an example, the method may further comprise determining a spatial relationship between a first geochemical zone and a second geochemical zone.

In an example, the spatial relationship may be an overlap between the first geochemical zone and the second geochemical zone.

In an example, the method may further comprise generating a description of the overlap between the first geochemical zone and the second geochemical zone. The description may state properties of the overlap.

In an example, the method may further comprise generating a description of the spatial relationship. The description may use natural language terms interoperable with human knowledge on a computer.

In an example, the method may further comprise determining, using computer reasoning, mineral deposit types and mineral deposits matching the description of the spatial relationship.

For the purposes of illustration, some examples provided herein may describe how the DRIVER system may be applied to data associated with Achmmach Sn skarn project in Morocco (“the Achmmach project”). However, one skilled in the art would understand that such examples are provided for the purpose of simplicity and that the embodiments described herein may be applied to other data and/or other locations.

The DRIVER system may use and/or analyze data associated with a drilling of a deposit at a location. For example, the DRIVER system may use and/or analyze data from a database associated with drilling of the deposit at the Achmmach project deposit. The Achmmach deposit is a Tin (Sn) skarn and DRIVER output provide an evaluation with respect to various aspects of the deposit. The evaluation may include an indication of an agreement between DRIVER output data and one or more structural elements that may be controlling Tin mineralization at the deposit; one or more spatial relationships between different metals (e.g., Ag, Pb, Sn and Zn); one or more potential implications for a subsequent evaluation; an indication of multi-element overlaps; a comparative mineral deposits analysis that may be world-wide, which may serve to provide insights with respect to subsequent evaluation of the deposit; and the like.

The DRIVER system may deliver results of DRIVER data outputs in open standard formats (e.g., Geoscience Analyst). DRIVER may use AI technology, such as Cognitive AI technology, to report which identified spatial patterns are of possible economic importance to the mineral deposit under evaluation, and a context within which they may be important. The DRIVER system may deliver Cognitive AI outputs in natural language to make them actionable by users, which may be non-AI-trained personnel. The DRIVER system may enhance AI outputs (e.g., Cognitive AI outputs) with related technical documentation delivered within a language extension system and/or a language organization system (e.g., Minerva's Language Extension and Organization system (LEO)).

Depending on the maturity of the data set being analyzed, DRIVER's contribution to understanding the mineral deposit or target may vary. For example, the DRIVER system output for purely exploration data sets may be a primary contribution to exploration insights (e.g., identification of prominent element enrichment directions facilitating suggested vectors for future drilling). Output from data sets from a producing mine may provide insights towards peripheral resource expansion and may also inform aspects of the mine's metallurgy, environmental footprint, and other mining considerations (e.g., if lithogeochemical proxies for ground conditions are known, or can be identified). Results from the DRIVER system may be delivered in the form of wireframes (e.g., in .dxf format), block models (which may be delivered in a number of formats, such as in a .csv format). Results from the DRIVER system may be delivered to and/or accessed from a dedicated online user interface (UI) platform where detailed directional analysis data interrogation may be conducted.

The DRIVER system may enhance the interpretation of drilling data. Over many years mineral deposit specialists have documented different geochemical zonation patterns recognizable in different mineral deposit types. These zonations may be present in the element that may not be economically important and may be used to infer where to find orebody extensions and to identify ore which may have different metallurgical or mineability characteristics. The DRIVER system may use knowledge representation technology (e.g., a branch of artificial intelligence) to express a broad and growing range of this zonation knowledge. The DRIVER system may use that knowledge to identify zonation patterns in input data sets that may be of value to a user, such as the data set owner.

Because mineral deposits may be rotated and deformed, the DRIVER system may look for these zonation patterns in multiple models created with multiple variations in interpolation anisotropy.

The DRIVER system may use cognitive AI technology to integrate human knowledge such that the interpretation of mineral exploration drilling results may be provided and/or automated. For example, the DRIVER system may manage a combinatorially-explosive number of patterns to evaluate by applying one or more thresholds to various feature extraction parameters. The DRIVER system may provide an ability to report potentially valuable patterns in exploration drilling results to the owners of those results more efficiently than previously possible.

The systematic application of well-structured human knowledge to multiple models of input drilling data may enable the DRIVER system to be more rigorous. For example, the DRIVER system may be more rigorous in ensuring that a number (e.g., a large number) of zonation patterns (e.g., potentially-important zonation patterns) may have been searched for in the input data, identified, and/or reported if found to be present.

The DRIVER system may provide exploration and metallurgical value. There may be at least two aspects of the mining value chain that the DRIVER system may addresses; the exploration stage, and the ore body evaluation and planning stages. During the exploration stage, finding more mineralization may be the principal goal, and thus multi-element clues as to where further extensions of the ore body may be located may save a company time and money. The presence of deleterious or penalty elements (e.g., cadmium, arsenic) alongside the economic elements (e.g., gold, copper, zinc) may be important for geometallurgical and mine planning reasons. A gold orebody with arsenic-rich and arsenic-poor zones may need a different mine plan than a similar orebody without arsenic complications. The earlier a project manager may be aware of these relationships, the more effectively they may plan their mine.

The DRIVER system may identify anomalous geochemical zones and patterns of potential economic significance. Clusters of block values within the models may be identified that may be higher or lower (e.g., significantly higher or lower) than their surrounding block values and may b. se tagged as anomalous. Discrete (non-contiguous) clusters of anomalous block values may be determined and may one or more discrete clusters (e.g., each discrete cluster) may be named. One or more such clusters (e.g., each such cluster) may be considered to represent a geochemical zone. Spatial relationships between such zones of different elements may be identified. For example, an extent of zone overlap may be identified, which may be aggregated over the entire study volume, or in individual zones. Cognitive artificial intelligence (AI) technology may be used to report which identified spatial patterns may be of possible economic importance to the mineral deposit being evaluated, and why they may be important.

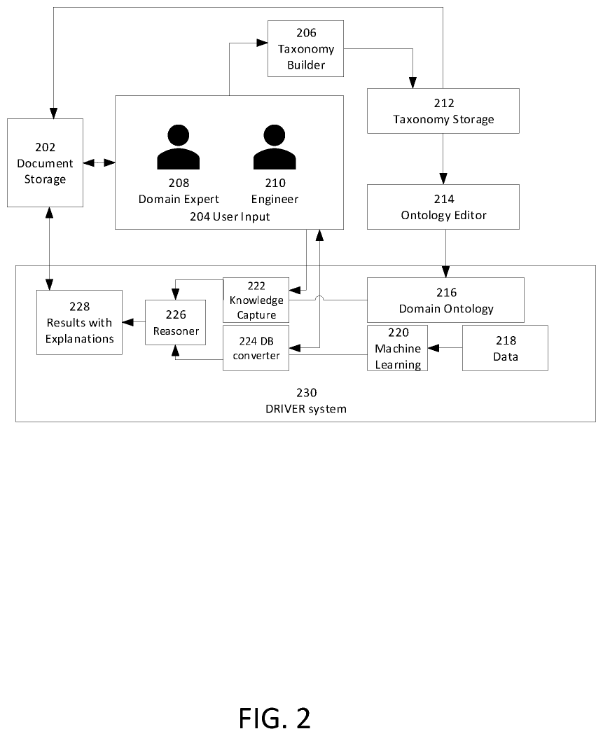

FIG. 2 shows an example flow diagram integrating artificial intelligence (e.g., cognitive artificial intelligence) into the DRIVER system. For example, FIG. 2 may illustrate how a DRIVER system may incorporate artificial intelligence (AI) to provide results with explanations.

Document storage 202 may be provided. Document storage 202 may use a vocabulary (e.g., a controlled vocabulary) to index and/or tag files. For example, document storage 202 may use a taxonomy received from taxonomy storage 212 to index and/or tag files. Document storage 202 may store structured documents and/or unstructured documents. Document storage 202 may store data, such as data from user input 204 and/or data output by the DRIVER system 230.

Domain expert 208 and/or engineer 210 may provide user input 204. Engineer 210 may be a user that may have an understanding of the DRIVER system. For example, engineering 210 may assist in capturing knowledge from a domain expert into a computable vocabulary. Domain expert 208 may be a person with knowledge and/or skills in a particular area of endeavor, such as medicine, accounting, software, geology, and the like.

User input 204 may be stored and/or provided to document storage 202. Document storage 202 may be a database, a computer, a sever, and the like for storing documents.

User input 204 may be provided to taxonomy builder 206. For example, domain expert 208 and/or engineer 210 may analyze definitions to identify the differentiating properties, establishing the value hierarchies for those properties, and assigning property values to terms such that the inferred hierarchy may be conceptually valid. Such input may be provided to taxonomy builder 206 and/or may be created using taxonomy builder 206. For example, domain expert 208 and/or engineer 210 may use taxonomy builder 206 to develop and maintain logically coherent, computable vocabularies.

Taxonomy builder 206 may be provided. Taxonomy builder 206 may provide tools for creating and/or editing vocabularies, taxonomies, and/or ontologies. For example, users, such as domain expert 208 and/or engineer 210, may use taxonomy builder 206 to create and/or edit vocabularies, taxonomies, and/or ontologies. Taxonomy builder 206 may provide a high-level ontology editors that may compile to lower level languages. Taxonomy builder 206 may implement a design pattern, such as defining a class, identifying a superclass, and stating how this may differ from other children of that superclass. This design pattern may result in natural definitions, which may be easier for humans and computers to reason

Taxonomy storage 212 may be provided. Taxonomy storage 212 may provide stored taxonomies to document storage 202.

Taxonomy storage 212 may store a taxonomy provided by taxonomy builder 206. A taxonomy may be a hierarchy of concepts. For example, a taxonomy may be a hierarchical system of concepts in which the child concepts have a relationship to the parent concept. In such a hierarchy, any instance of a child concept may also be an instance of its parent concept. A taxonomy may have a top concept that may be a general kind of entity (e.g., the most general kind of entity) included in the system. The children of a specific concept in the taxonomy may be referred to as siblings, following the family metaphor that is typically used. A taxonomy may have a tree structure, in which a concept (e.g., each concept with exception of the top concept) has one parent. A directed acyclic graph is a more general hierarchical structure in which a concept may have multiple parent concepts.

In an example, a taxonomy may be provided for geologists, which may use scientific vocabulary to describe their exploration targets and the environments they occur in. The words in these vocabularies may occur within sometimes complex taxonomies, such as the taxonomy of rocks, the taxonomy of minerals, and the taxonomy of geological time, and the like.

Ontology editor 214 may be provided. An ontology may be determined using one or more taxonomies. An ontology may be concepts that are relevant to a topic, domain of discourse, an area of interest, and/or the like. For example, an ontology may be provided for information technology, computer languages, a branch of science, medicine, law, geology and/or other expert domains. An ontology may incorporate one or more taxonomies into a reasoning.

For example, geologists may use a scientific vocabulary to describe their exploration targets and the environments they occur in. The words or terms in these vocabularies may occur within one or more taxonomies, such as the taxonomy of rocks, the taxonomy of minerals, and the taxonomy of geological time, to mention only a few. An ontology may incorporate these taxonomies into a reasoning such that the ontology may indicate that that basalt is a volcanic rock, but granite is not.

Ontology editor 214 may allow a user, such as domain expert 208 and/or engineer 210, to create and/or edit an ontology. The ontology editor 214 may provide an ontology to domain ontology 216, such that the ontology may be accessible to the DRIVER system 230.

The DRIVER system 230 may comprise domain ontology 216, data 218, machine learning 220, knowledge capture 222, database (DB) converter 224, reasoner 226, and results with explanations 228.

Domain ontology 216 may include an ontology that may enable interoperability and systematic reasoning. For example, domain ontology 216 may include an ontology that may be used by a geologist, such as domain expert 208. The ontology be for the description of mineral deposits.

Data 218 may include any data that may be relevant to geological analysis of a location. For example, data 218 may include models, such as deposit models; mining data, mineral data, multi-element drilling data, and the like.

Machine learning 220 may include supervised or unsupervised machine learning. For example, machine learning 220 may provide supervised machine learning as part of a data processing chain to provide feature extraction, such as zone recognition. As another example, machine learning 220 may apply unsupervised machine learning technology to identify anomalous single and/or multi-element geochemical zones.

Knowledge capture 222 may be used to capture knowledge, such as domain information from a user, which may be domain expert 208 and/or engineer 210.

Database (DB) converter 224 may be used to convert data from one database to another. For example, data stored in one database may not be stored in a format that may be compatible with data stored in another database. To allow for the data to be used fluidly, DB converter 224 may interface with both databases such that the data maybe made compatible.

Reasoner 226 may provide computer reasoning and/or knowledge matching. For example, reasoner 226 may be used to compare output data created by the DRIVER system against a database of mineral deposits and mineral deposit types.

Results with explanations 228 may provide a user with results from an analysis provided by the DRIVER system. Results with explanations 228 may provide a user with an explanation of how the results were reached. For example, multi-element relationships may be identified and may be checked against mineral deposit knowledge to provide recommendations.

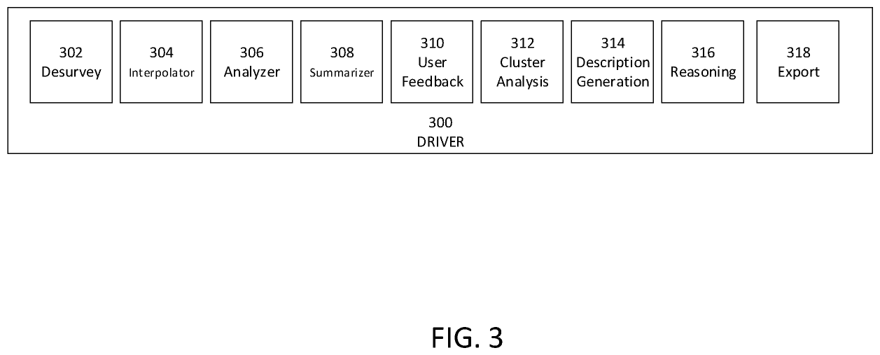

A DRIVER system may be modularized. FIG. 3 shows an example illustration of one or more modules that may be used in a DRIVER system. For example, as shown in FIG. 3, the DRIVER system 300 may have one or more modules. The one or more modules may be daisy-chained together such that outputs from one module may serve as inputs to a next module.

In an example, the DRIVER system may be able to process a set of input data from beginning to end without human intervention. The DRIVER system may be structured so as to allow human intervention at different stages of the daisy-chain. For example, human intervention may be used to vary one or more signal processing parameters that may control the sensitivity of an element (e.g., a single element) and/or multi-element zone-identification algorithms.

As shown in FIG. 3, the DRIVER system 300 may incorporate a number of modules. For example, the DRIVER system 300 may comprise one or more of desurvey module 302, interpolator module 304, analyzer module 306, summarizer module 308, user feedback module 310, cluster analysis module 312, description generation modules 314, reasoning module 316, and export module 318.

The DRIVER system 300 may comprise the desurvey module 302. The desurvey module 302 may processor raw survey and/or interval data. The desurvey module 302 may desurvey the raw survey data and/or the interval data. For example, desurvey module 302 may computes the geometry of a drillhole and the location of samples in a three-dimensional space based on a collar location, an inclination, an azimuth, a direction, and/or a depth of samples along the drillhole.

The DRIVER system 300 may comprise the interpolator module 304. The interpolator module 304 may take the initial drillhole data and may create interpolations for X search-rotation-combinations (SRCs) and Y element. The interpolator module 304 may interpolate element concentrations into block models using one or more anisotropies.

The DRIVER system 300 may comprise the analyzer module 306. The analyzer module 306 may analyze one or more SRCs for spatial relationships that may be present between geochemical zones. The analyzer module 306 may provide aggregated overlap analysis. The analyze module 306 may provide cluster overlap analysis. The analyze module 306 may provide concentration volume plots.

The DRIVER system 300 may comprise the summarizer module 308. The summarizer module 308 may evaluate the interpolations and may summarize geochemical zones.

The DRIVER system 300 may comprise the user feedback module 310. The user feedback module 310 may allow a user, such as a geologist to select a subset of the one or more SRCs. For example, the geologist may zoom in on the subset of the one or more SRCs for a detailed analysis.

The DRIVER system 300 may comprise the cluster analysis module 312. The cluster analysis module 312, may perform a statistical analysis of the clusters to identify optimal anisotropies for each element. The space occupied by each optimal cluster for each element is surrounded by a wireframe representing a geochemical zone.

The DRIVER system 300 may comprise the description generation module 314. The DRIVER system 300 may identify an overlap between a first geochemical zone and a second geochemical zone. The description generation module 314 may generate a description that states the properties of the overlap.

The DRIVER system 300 may comprise the reasoner module 316. The reasoner module 316 may provide computer reasoning and/or knowledge matching. For example, the reasoner module 316 may be used to compare output data created by the DRIVER system against a database of mineral deposits and mineral deposit types.

The DRIVER system 300 may comprise the export module 318. The export module 318 may be used to export objects from one or more processes and/or modules.

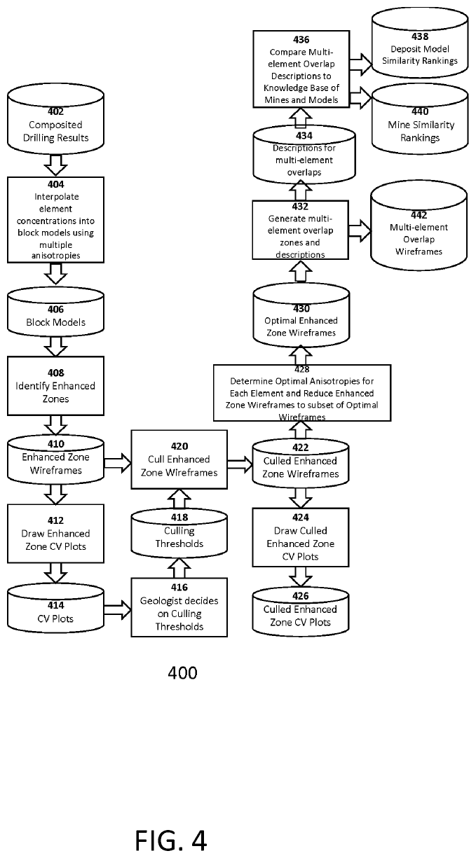

FIG. 4 shows an example flow diagram for providing a drilling interpretation and volumes estimator. The example flow diagram may show a workflow that may be used by the DRIVER system to provide output data and/or results.

At 402, composited drilling results may be received. The composited drilling results may include geochemical concentrations or properties sampled at regular intervals (e.g., 2 meters) along the drillhole length.

At 404, the DRIVER system may interpolate the composited drilling results into block models, such as the block models 406. A block model may be a collection of blocks used to model a volume of the solid earth greater than the size of a single block.

At 408, the DRIVER system may use block models 406 to identify clusters of blocks. A cluster within the cluster of blocks may be a group of blocks with a common property that separate or distinguish them from surrounding blocks. A cluster of blocks with an enhanced concentration with respect to surrounding block values may be referred to as an enhanced zone or a geochemical zone. The DRIVER system may encapsulate these enhanced zones into wireframes. These wireframes may be referred to as enhanced zone wireframes and may be viewable.

At 412, The DRIVER system may use the enhanced zone wireframes 410, to draw enhanced zone CV plots 414. Evaluation of the enhanced zones may be facilitated by plotting the average concentration (C) with respect to volume (V) for every enhanced zone identified, resulting in a “CV plot” for each element under evaluation.

At 416, the DRIVER system may receive feedback from a user, such as a geologist. The geologist may decide on culling thresholds 418 based on CV plots 414. The geologist may provide the culling thresholds 418 to the DRIVER system. A culling threshold may be an average concentration and/or volume of an enhanced zone.

At 420, the DRIVER system may cull enhanced zone wireframes using the enhanced zone wireframes 410 and the culling thresholds 418.

At 424, the DRIVER system may draw the culled enhanced zone CV plots 426 using the culled enhanced zone wireframes 422.

At 428, an optimal anisotropy for each element may be determined from the culled enhanced zones by performing a statistical directional analysis on the culled enhanced zones for each element. The enhanced zone wireframes may be reduced to a subset of optimal enhanced zone wireframes at 430 using the optimal anisotropy for each element. The optimal anisotropy may be an anisotropy that may represent a distribution of a variable in the volume or space modeled. For example, the optimal anisotropy may be anisotropy which best represents the true distribution of the variable in the volume or space modeled.

At 432, the DRIVER system may evaluate the relationship between enhanced zones and may identify zones of overlap between enhanced zone wireframes using culled enhanced zone wireframes 422. The DRIVER system encapsulate the zones of overlap within wireframes and may output overlap zone wireframes 442.

At 432, the DRIVER system may generate descriptions of each overlap zone and a description may state the properties of the overlap. The descriptions may be provided at 434.

At 436, given descriptions for each overlap zone may be compared with a database of mineral deposits and mineral deposit types. DRIVER may output deposit model similarity rankings 438 and mine similarity markings 440.

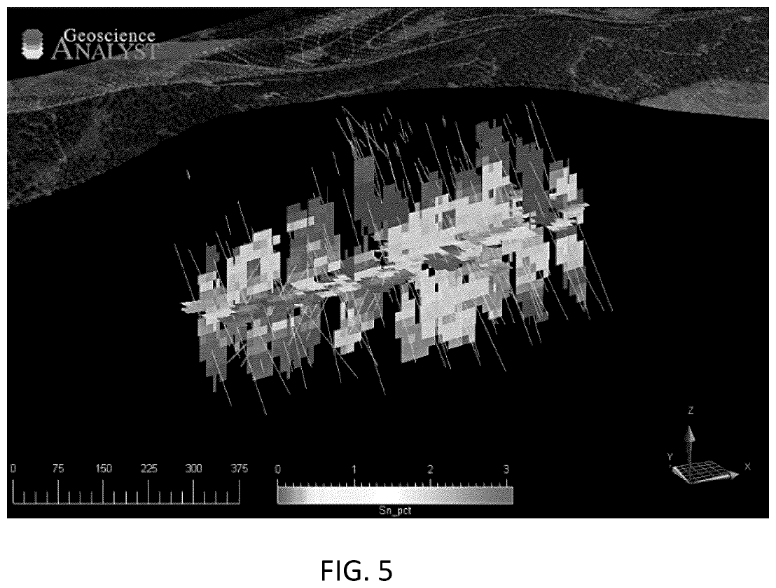

FIG. 5 shows an example block model as displayed in a 3D software. For example, FIG. 5 illustrates an example block model in a 3D software in a view looking northeast. The example block model may be a block model from the Achmmach project that shows interpolated concentration of Sn (pct) under an optimal anisotropy.

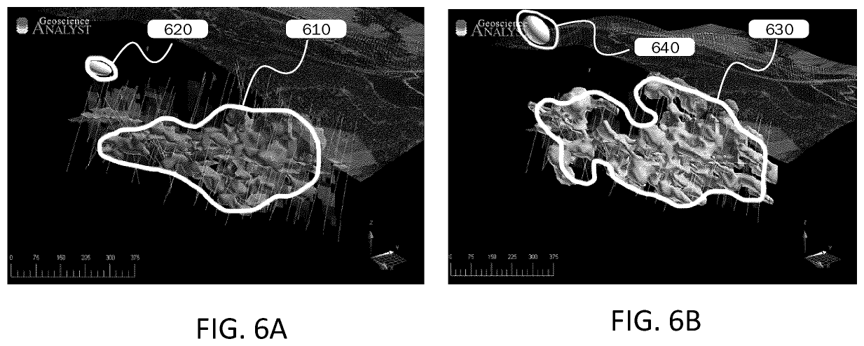

FIGS. 6A-B show examples of enhanced zone wireframes. For example, FIGS. 6A-B show examples of enhanced zone wireframes for Tin (Sn) identified at the deposit of the Achmmach project (e.g., looking northwest).

The DRIVER system may implement an algorithm that quantifies the spatial relationships between interpolated block values, such as a 3-dimensional implementation of LISA (Local Indicator of Spatial Autocorrelation). The DRIVER system may pair the spatial relationships, for example with DBSCAN (e.g., density-based spatial clustering of applications with noise), to group the correlated data into enhanced zones.

FIG. 6A outlines an enhanced zone wireframes 610 with an average concentration of 0.90 pct Sn and volume of 6.38 M m3. FIG. 6B shows the same enhanced zone wireframes at 630 represented using a different anisotropy. Enhanced zone wireframes 630 is larger, but lower grade at 0.76 pct Sn and 18.85 M m3. A 3D ellipsoid mesh (shown as 620 and 640 in FIG. 6A and FIG. 6B, respectively) illustration the anisotropy used in creating the block model may be included by DRIVER to assist the user in evaluation.

The DRIVER system may include a clustering evaluation (e.g., CV plots). Evaluation of zones of element enhancement may be facilitated by plotting the average concentration (C) with respect to volume (V) for every cluster identified, resulting in a “CV plot” for each element under evaluation. Each point on this plot represents a discrete enhanced-element zone identified by DRIVER, under every anisotropy evaluated. The point colors on DRIVER CV plots may represent the ellipsoid aspect ratios for the anisotropies used to generate the models.

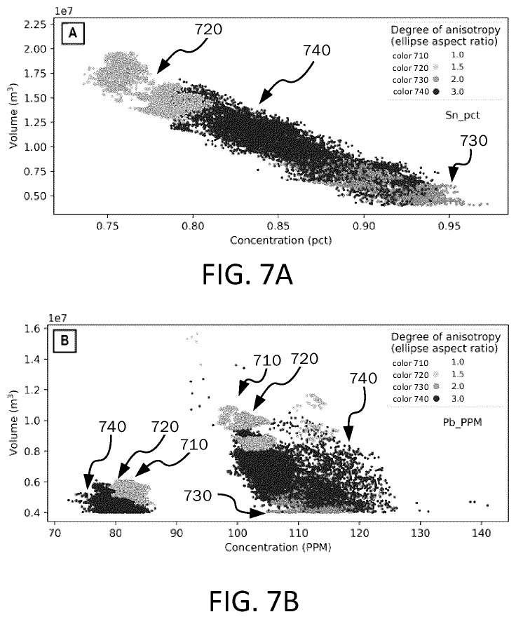

FIG. 7A-B show example concentration (C) with respect to volume (V) plots (CV plots). For example, FIGS. 7A-B illustrate CV plots for Sn (pct) and Pb (ppm) identified at the deposit of the Achmmach project.

Individual CV plots may display discrete groups of points, having different shapes and slopes in CV space (e.g., as shown in CV plots for Sn (pct) in FIG. 7A and Pb (ppm) in FIG. 7B). Different colors represent different ellipsoid aspect ratios for each anisotropy. For example, colors 710, 720, 730, 740 represent ellipsoid aspect ratios 1.0, 1.5, 2.0, 3.0, respectively. As shown in FIG. 7A, the volume of Sn clusters is negatively correlated with concentration. As shown in FIG. 7B, the negative correlation between the volume of Pb and the concentration is less pronounced. There are two groups evident in the CV plot for Pb, a small group, having low concentration and volume, to the lower left, and the main group, having higher concentrations and larger volumes to the right. As shown in FIGS. 7A-B, each group commonly represents a certain location in Euclidean space (having different x, y, z coordinates for each member of a group and the center of the group as a whole). Groups may also combine under certain anisotropies to create additional groups within the CV space. A group (e.g., each group) may be identified automatically and evaluated by the DRIVER system. Larger groups may provide important geometrical representation of the major ore zone(s), while smaller groups may provide valuable information with respect to potential alteration and/or peripheral mineralization.

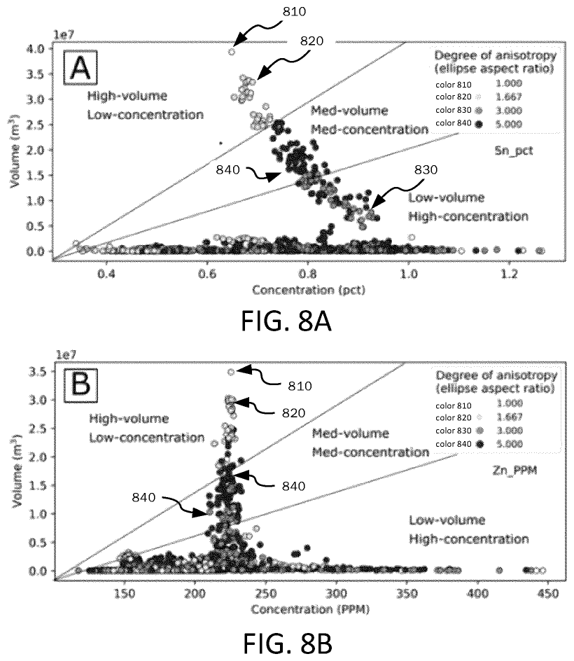

FIGS. 8A-B show example CV plots that consider an ellipsoid aspect ratio. For example, as shown in FIGS. 8A-B, colors 810, 820, 830, 840 represent ellipsoid aspect ratios 1.000, 1.667, 3.000, 5.000, respectively. Ellipsoid aspect ratio in concentration-volume plots may be evaluated. Small isotropic search radii may produce high-concentration, low-volume clusters, while large isotropic search radii may produce high-volume, low-concentration clusters. The clusters located between these end-member limits may reflect the effect on different anisotropies on the distribution of element concentrations.

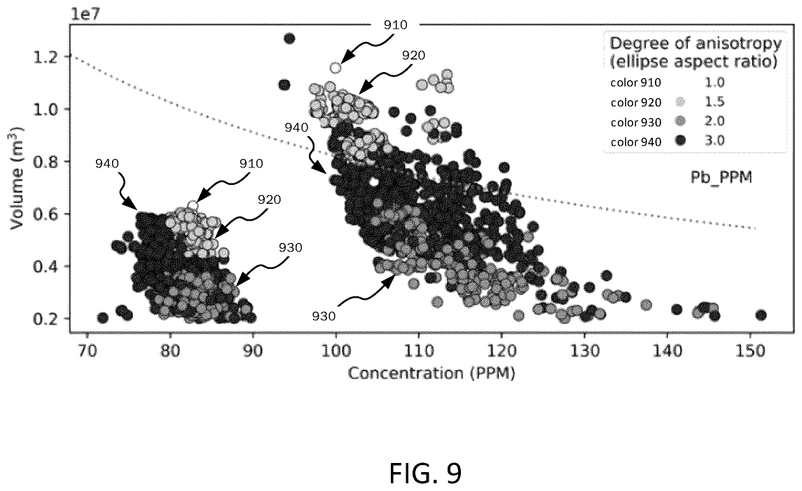

FIG. 9 shows an example CV plot of Pb in an example deposit. Colors 910, 920, 930, 940 may represent ellipsoid aspect ratios 1.0, 1.5, 2.0, 3.0, respectively. The plotted data of Pb (ppm) may represent Pb in the deposit of the Achmmach project. The data may be divided into two distinct groups, each of which represent an individual, spatially discrete enhanced zone of Pb.

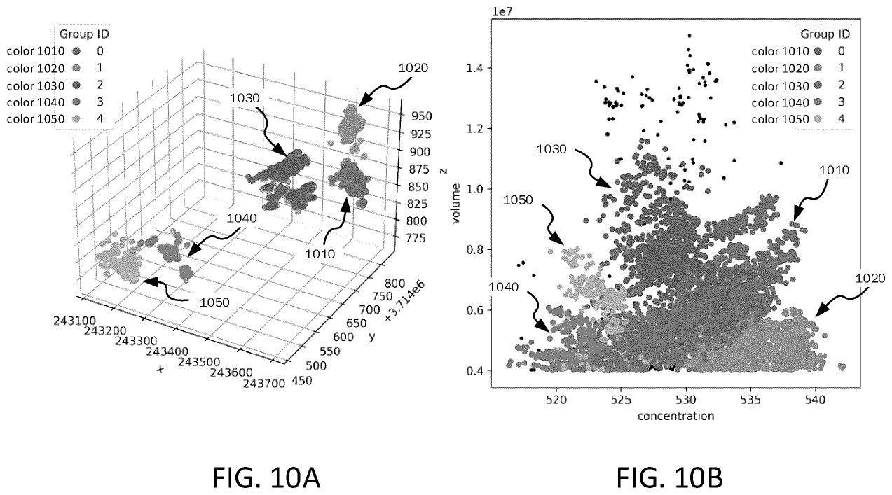

As shown in FIG. 9, the grouped clouds may be discrete. In many instances the clouds may overlap, forming complicated CV plot distributions. FIG. 10A-B show an example distribution of data grouped into spatially discrete cluster groups. The data may represent distribution of Ba in the deposit of the Achmmach project. Colors 1010, 1020, 1030, 1040, and 1050 represent cluster group IDs 0, 1, 2, 3, and 4 respectively. As shown in FIG. 10A, the 3D view of Ba consists of at least 5 spatially discrete zones of enhanced element concentrations. Multi-dimensional clustering described herein may be used to automatically identify these groups. As shown in FIG. 10B, in regular CV space, these groups may be difficult (e.g., may be extremely difficult) to distinguish.

The DRIVER system may choose optimal anisotropies for each element. The DRIVER system may interpolate element concentrations using many possible anisotropies (e.g., tens of thousands). The results may be evaluated to identify optimal anisotrop that represent the deposit in a realistic way (e.g., the most realistic way possible). The DRIVER system may perform optimal ansiotropy analysis of the vast quantify of data produced automatically.

The DRIVER system may choose a metric to determine an optimal anisotropy. A metric used to determine an optimal anisotropy may change (e.g., depending on the result desired by the user). For example, the anisotropy that produces a high element concentration may be considered optimal. As another example, the anisotropy that produces the largest quantity of contained metal may be considered optimal.

The DRIVER system may use multi-dimensional clustering to group clusters of enhanced element zones. A stage may use multi-dimensional clustering to group the clusters of enhanced element zones in terms of their properties (e.g., size, concentration, surface area, and the like) and physical location in space. The clusters may be grouped using a high-dimensional distance-based algorithm (e.g., DBSCAN). In DRIVER, cluster grouping may be performed on an element-by-element basis (e.g., semi-autonomously under the guidance of the user). Two parameters may be adjusted to manipulate the grouping algorithm. The dimensions (e.g., parameters) used for cluster grouping may be selected from: x, y, z, concentration, volume, and surface area. The search distance-eps parameter may be adjusted to allow more, or less spatially related points to be grouped. The number of clusters parameter may be adjusted to identify more, or less cluster groups. To simplify the outputs of optimal ansiotropy analysis, DRIVER may group the data into the smallest number of groups possible, while still maintaining reasonable data segregation (e.g., several). The number of groups may range from 1 to 10.

In a stage of optimal anisotropy analysis, each element may be evaluated for an anisotropy (or limited collection of anisotropies) that may represent the best anisotropy to represent that element in the deposit.

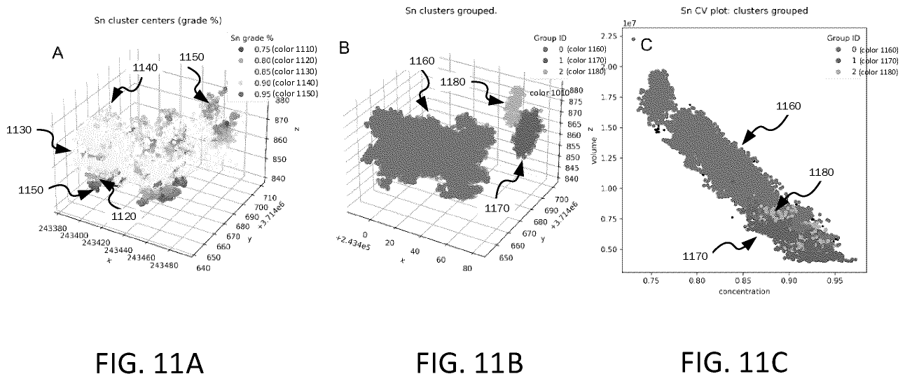

FIGS. 11A-C show example Tin (Sn) groups arising from optimal anisotropy analysis for an example deposit. The example deposit may be from the Achmmach Project. Colors 1110, 1120, 1130, 1140, and 1150 represent Sn grade % 0.75, 0.80, 0.85, 0.90 and 0.95 respectively. Colors 1160, 1170, and 1180 represent cluster group IDs 0, 1, and 2, respectively. As shown in FIG. 11A, spatial variations in tin grade in the sub-surface are displayed. Each point may be an average cluster location in Euclidean space. As shown in FIG. 11B, three main groups of clusters are identified. As shown in FIG. 11C, relationship between the three groups are displayed on a CV plot for Sn. A cluster may be referred to as an enhanced zone.

The DRIVER system may flag combination cluster groups. In many cases, selected anisotropies may orient in such a direction so that multiple clusters of elevated concentration join to form a (e.g., a larger) combination cluster/group. This group may be identified as a discrete group on the concentration-volume space plots.

The DRIVER optimal anisotropy analysis may automatically identify these potential combination groups using a method that evaluates the location of each group along a line. If a group is situated between two other groups, these two groups may be referred to as the parent groups. If the count of points in the group is consistent with (e.g., less than) the number in the smaller parent group, the group may be automatically flagged and removed from future analysis.

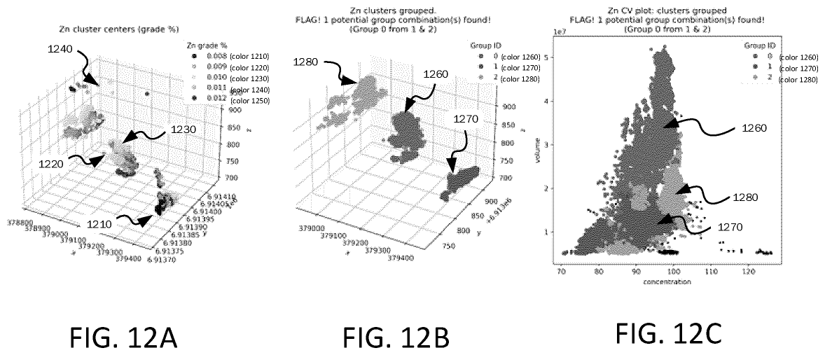

FIGS. 12A-C show discount groups that may be identified for Zn. For example, FIGS. 12A-C illustrate three distinct groups identified for Zn. The largest group, group 0, is produced when the two peripheral zones join (e.g., under certain anisotropies). Colors 1210, 1220, 1230, 1240, and 1250 represent Zn grade % 0.008, 0.009, 0.010, 0.011 and 0.012, respectively. Colors 1260, 1270, and 1280 represent cluster group IDs 0, 1, and 2, respectively.

DRIVER workflow may perform cluster angular-rotation-series analysis. Taking the single anisotropy that produces the maximum contained metal may not be a reliable method for evaluating which anisotropies may be present in the data. DRIVER may perform an angular-rotational series analysis to extract repeated patterns in the data that represent the statistically supported, best anisotropy to use in future analysis. A stage of such analysis may be to order/sequence the data in terms of the search parameters and angular rotations (that may define an anisotropy) that were applied during each interpolation stage. This process may be similar time-series signal analysis except, instead of time, the data are ordered in terms of their sequential geometric rotations. This process may allow each angular cycle to be evaluated independently. The anisotropy that provides the strongest performance may be included in a population of data that represents a subset of candidate anisotropies.

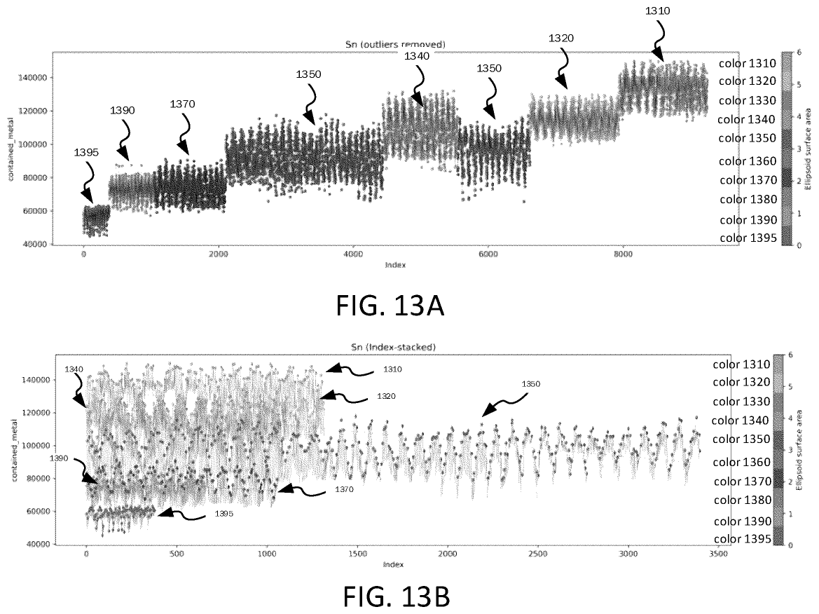

FIGS. 13A-B show example representations of ellipsoid surface area data. For example, as shown in FIGS. 13A-B, colors represent a number of sub-ranges of ellipsoid surface area on an indexed scale of 0-6. Colors 1310, 1320, 1330, 1340, 1350, 1360, 1370, 1380, 1390, and 1395 represent 10 such sub-ranges. As shown, color-coded markers represent ellipsoid surface area data (e.g., “contained metal” volume of Sn as the y axis) with respect to a geometric rotation index (e.g., as the x axis). FIG. 13B illustrate show population selected for statistical, directional evaluation using color-coded markers.

DRIVER may perform a statistical direction analysis using a frequency analysis procedure. Anisotropies that form planar geometries (e.g., a pancake or a disc) may be classified by their strike and dip. Anisotropies that form linear geometries (e.g., a football) may be classified by their trend and plunge. Triaxial (e.g., scalene) ellipsoids possess both a trend and plunge and a strike and dip and may be considered in both the planar and linear cases. DRIVER may classify linear and planar (e.g., all linear and planar) optimal anisotropies using the right-hand rule.

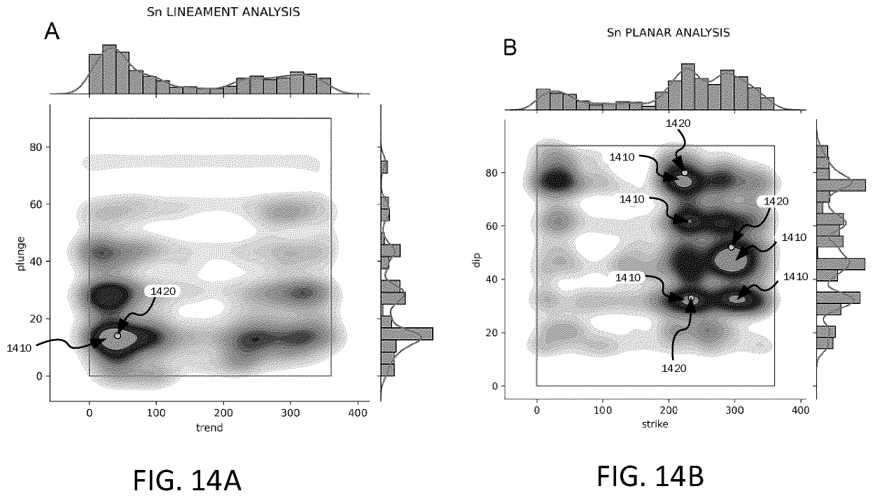

To visualize the results of frequency analysis, DRIVER may produce a bi-variate histogram. FIGS. 14A-B show examples of bi-variate histograms. For example, FIGS. 14A-B show graphical representations of optimal anisotropy analysis for Sn. Plots for either the preferred flattened disc (shown in FIG. 14B as Strike vs Dip) or “football” (shown in FIG. 14A as Trend vs Plunge) are provided in the sub-directory for each element. Histograms along the x-axis, as strike (shown in FIG. 14B) or trend (shown in FIG. 14A), and y-axis, as dip (shown in FIG. 14B) or plunge (shown in FIG. 14A), plotted as bi-variate histograms for representative population distributions. The markers 1420 may indicate automatically chosen linear and planar analysis distribution peaks (e.g., anisotropies where the optimal anisotropic metric (in this case, high contained metal)) is most frequently met. The peaks (e.g., markers 1410) on these plots may represent the anisotropies that best achieve the optimal anisotropic metric and are supported, statistically by a large subset of values. Up to 5 peaks may be automatically located using a local maxima identification. The largest peak (e.g., the peak supported by the most occurrences) may represent the dominant structural trend found in the data. Smaller peaks may represent subordinate structural anisotropies.

The results of DRIVER optimal anisotropy analysis may include figures and tables with each (e.g., planar and/or linear) optimal anisotropy identified for each element; and the optimal cluster zones for each element. The results of optimal anisotropy analysis may be discussed in the context of the deposit of the Achmmach project.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed:

1. A device for modeling anomalous geochemical zones, the device comprising:
a memory, and
a processor, the processor configured to:
determine block values by interpolating, using various anisotropies, multi-element assay results from drill hole samples into contiguous blocks used to model a volume sampled by drilling;
identify clusters of the block values for an element within each of multiple models representing the various anisotropies, the clusters indicating which block values are anomalous to one or more surrounding block values;
determine an optimal anisotropy for each element from the identified clusters by performing a statistical directional analysis on the identified clusters for each element; and
surround a space occupied by each cluster associated with the optimal anisotropy for each element, with a wireframe, each representing a geochemical zone.

2. The device of claim 1, wherein the statistical directional analysis on the identified clusters comprises at least a frequency analysis on properties of the identified clusters.

3. The device of claim 1, wherein the processor is further configured to determine a spatial relationship between a first geochemical zone and a second geochemical zone.

4. The device of claim 3, wherein the spatial relationship is an overlap between the first geochemical zone and the second geochemical zone.

5. The device of claim 4, wherein the processor is further configured to generate a description of the overlap between the first geochemical zone and the second geochemical zone, and wherein the description states properties of the overlap.

6. The device of claim 3, wherein the processor is further configured to generate a description of the spatial relationship, wherein the description uses natural language terms interoperable with human knowledge on a computer.

7. The device of claim 6, wherein the processor is further configured to determine, using computer reasoning, mineral deposit types and mineral deposits matching the description of the spatial relationship.

8. A device for modeling anomalous geochemical zones, the device comprising:
a memory, and a processor, the processor configured to:
determine block values by interpolating, using various anisotropies, multi-element assay results from drill hole samples into contiguous blocks used to model a volume sampled by drilling;
identify clusters of the block values for an element within one or more models representing the various anisotropies, the clusters indicating which block values are anomalous to one or more surrounding block values;
determine an optimal anisotropy for each element from the identified clusters by performing a statistical directional analysis on the identified clusters for each element;
surround a space occupied by each cluster associated with the optimal anisotropy for each element, with a wireframe, to represent a geochemical zone;
determine a spatial relationship between a first geochemical zone and a second geochemical zone.

9. The device of claim 8, wherein the statistical directional analysis on the identified clusters comprises at least a frequency analysis on properties of the identified clusters.

10. The device of claim 8, wherein the spatial relationship is an overlap between the first geochemical zone and the second geochemical zone.

11. The device of claim 10, wherein the processor is further configured to generate a description of the overlap between the first geochemical zone and the second geochemical zone, and wherein the description states properties of the overlap.

12. The device of claim 8, wherein the processor is further configured to generate a description of the spatial relationship, wherein the description uses natural language terms interoperable with human knowledge on a computer.

13. The device of claim 12, wherein the processor is further configured to determine, using computer reasoning, mineral deposit types and mineral deposits matching the description of the spatial relationship.

14. A method being performed by a device for modeling anomalous geochemical zones, the method comprising:
determining block values by interpolating, using various anisotropies, multi-element assay results from drill hole samples into contiguous blocks used to model a volume sampled by drilling;
identifying clusters of the block values for an element within each of multiple models representing the various anisotropies, the clusters indicating which block values are anomalous to one or more surrounding block values;
determining an optimal anisotropy for each element from the identified clusters by performing a statistical directional analysis on the identified clusters for each element; and
surrounding a space occupied by each cluster associated with the optimal anisotropy for each element, with a wireframe, each representing a geochemical zone.

15. The method of claim 14, wherein the statistical directional analysis on the identified clusters comprises at least a frequency analysis on properties of the identified clusters.

16. The method of claim 14, wherein the method further comprises determining a spatial relationship between a first geochemical zone and a second geochemical zone.

17. The method of claim 16, wherein the spatial relationship is an overlap between the first geochemical zone and the second geochemical zone.

18. The method of claim 17, wherein the method further comprises generating a description of the overlap between the first geochemical zone and the second geochemical zone, and wherein the description states properties of the overlap.

19. The method of claim 16, wherein the method further comprise generating a description of the spatial relationship, wherein the description uses natural language terms interoperable with human knowledge on a computer.

20. The method of claim 19, wherein the method further comprises determining, using computer reasoning, mineral deposit types and mineral deposits matching the description of the spatial relationship.
